(19) United States
(12) Patent Application Publication
(10) Pub. No.: US 2010/0169154 A1
(43) Pub. Date: Jul. 1, 2010

(54) SYSTEM AND ASSOCIATED METHOD FOR PRODUCT SELECTION

(75) Inventors: Christian Rossing Kraft, Frederiksberg (DK); Ari Antero Aarnio, Espoo (FI)

Correspondence Address: DITTHAVONG MORI & STEINER, P.C., 918 Prince Street, Alexandria, VA, 22314, US

(73) Assignee: NOKIA CORPORATION, Espoo (FI)

(21) Appl. No.: 12/345,081

(22) Filed: Dec. 29, 2008

(51) Int. Cl. G06Q 30/00; G06Q 50/00; G06F 9/45; H03M 3/00

(52) U.S. Cl. 705/10; 705/26; 703/22; 455/419

(57) ABSTRACT

A system and associated method is provided for assisting a customer in selecting products based on profile information of the customer. Profile information may be obtained directly from the user and from information collected on the customer's mobile device. The profile information can be used to send the customer customized product proposals.

### BACKGROUND

When customers select new products, they often seek guidance or advice as to which products best suit their needs. They also generally prefer to interact with a product or product sample before purchasing it. In order to effectively aid in product selection, sales assistants often need to gather information from a potential customer. This information may be used to provide custom-tailored advice. In some cases, a customer may not be able or willing to provide the information that would facilitate selection of the most appropriate products for his needs or wants.

### BRIEF SUMMARY

This summary is not intended to identify any critical or key elements of the invention, but instead merely presents certain introductory concepts so that the full scope of the invention may be appreciated upon reading the full specification and figures, of which this summary is a part.

Aspects of the invention are directed to assisting customers in selecting goods or services. Products likely to meet a customer's needs are proposed based on the customer's profile information. The customer accepts or rejects the proposed products.

In some aspects of the invention, profile information is obtained directly from the user. In other aspects, profile information is collected automatically by the user's mobile device. In further aspects, profile information that is not currently known may be identified by presenting a test to the user.

Examples of tests include determining if a product would satisfy a customer by displaying a demonstration of the product and showing the user examples of device configurations to determine which example the user finds most suitable.

Further aspects of the invention are directed to transferring products, including software configurations, to a mobile device. A customer can accept a proposed product on his home computer and have the product sent to his mobile device directly.

In yet further aspects of the invention, new or existing mobile device software may be customized or configured using a computer, and the changes may propagate to the user's mobile device.

Other aspects and variations will be apparent upon reading the detailed description set forth below. The invention is not intended to be limited in any way by this brief summary.

### BRIEF DESCRIPTION OF THE DRAWINGS

The foregoing summary of the invention, as well as the following detailed description, is better understood when read in conjunction with the accompanying drawings, which are included by way of example, and not by way of limitation with regard to the claimed invention.

FIG. 1, one example embodiment of the invention, shows a user interface designed to assist customers in selecting an appropriately accessible mobile phone.

FIG. 2, one example embodiment of the invention, illustrates a computer running a mobile device emulator and interacting with an actual mobile device.

FIG. 3, one example embodiment of the invention, shows a mobile device in communication with a server.

FIG. 4, one example embodiment of the invention, shows a mobile device, a server, and a computer in communication with one another.

FIG. 5, one example embodiment of the invention, illustrates the flow of data that may occur in accordance with various embodiments of the present invention.

FIG. 6, one example embodiment of the invention, shows a flowchart including method steps for assisting customers with product selection.

FIG. 7, one example embodiment of the invention, shows an example of apparatus in which the principles of the invention can be practiced.

### TERMINOLOGY

The term “products,” as used in this document, includes both tangible and intangible goods. For example, a mobile phone and a carrying case are both products. Other examples of products include software applications; ringtones; keys, codes, or other information used to unlock functionality in existing software; and service or subscription plans. The term “products,” as used in this document, also encompasses services, such as the service of transferring software settings or configurations from one terminal to another. Examples include transfers from a computer to a mobile device, from a mobile device to a computer, from one mobile device to another, etc. The term “products,” as used in this document, also encompasses media files, such as images, audio, video, songs, multimedia, maps, point-if-interests (POI), and/or or any combination thereof. Examples include transfers from a computer to a mobile device, from a mobile device to a computer, from one mobile device to another, etc.

The word “customer” is used to describe someone who receives, potentially may receive, or views a product. A customer may also deliver a product in his possession to another customer. Use of the word “customer” is not intended to be limiting in any way. It is not meant to identify any particular pricing or subscription models. Any pricing or subscription model may be used in accordance with the present invention, including giving the products away for free and not selling or delivering the products at all.

The term “software,” as used in this document, includes any collection of instructions or code that can be executed on a processor or similar device. Examples of such devices include the microprocessors found in desktop computers, microcontrollers, and even certain FPGAs or ASICs. Software can be stored in a memory. Memories can be volatile or nonvolatile. Examples include random access memories (RAM) and read only memories (ROM), including hard disks, processor caches, flash chips or drives, EEPROMs, and any of a variety of other devices, as is well known in the art. Firmware is an example of software.

The term “terminal,” as used in this document, includes devices and apparatuses capable of sending and/or receiving communications over a data network. A data network is a network capable of transmitting data, even if it is also used for other transmissions. Examples of data networks include the internet, local area networks, and the networks used by wireless telephone and internet companies.

The term “profile information,” as used in this document, includes user information, user profiles, user terminal information, and the like. Examples of the user information include media consumption behavior, usage patterns, calendar information, contact information, media metadata information, playlists, etc. Examples of the user profiles include gender, age, income group, disabilities, stored application settings, etc. Examples of the user terminal information include user terminal type, the user terminal's technical capabilities, such as display type and size, internal memory size, communication capabilities, etc.

### DETAILED DESCRIPTION

In one aspect of the present invention, customers receive assistance in identifying products likely to meet their needs or wants. Customers can receive this assistance by interacting with a website. A customer can access the website from a variety of different types of terminals. For example, a customer can use a desktop computer, a thin client, a dedicated web browsing device, or a mobile phone.

Alternately, customers or potential customers, or users, can receive assistance in selecting products from a software application running on a terminal, including custom-made terminals, such as kiosks.

In another aspect of the present invention, profile/user information of a customer or potential customer is received. Profile information includes information associated with a customer or potential customer's preferences, desires, habits, abilities, past behavior, user terminal settings, account settings, demographic information, and the like. The customer or potential customer can provide profile information directly. For example, the customer can answer a question about what type of product he is looking for.

Alternately, or in addition, profile information can be retrieved automatically or semi-automatically. For instance, if a customer or potential customer has already answered a question or indicated a preference, that previous answer or indication may be retrieved without further input by the customer. Another example is to retrieve information about a customer's habits. If a customer sends many or few text messages on his mobile device, uses software applications in a certain pattern, uses many or few minutes of airtime on his mobile device, uses those minutes in a certain pattern, etc. that information can also be retrieved. Font, theme, volume, user interface configuration, screen brightness and contrast, and other such selections or preferences made on a device are also examples of profile information that can be retrieved automatically or semi-automatically.

In the case of certain devices and/or certain bits of profile information, extra measures may be required in order to make the profile information available for retrieval. For example, if a mobile device's contact list, volume settings, font settings, user interface settings, application usage patterns and/or data usage patterns are not otherwise available, software can be installed on the device that transmits this information upon demand, periodically, or when it is updated. A cache of some or all such profile information can be maintained for quick retrieval, or the information can be obtained upon demand.

By combining the customer's profile information with information about available products, products of potential interest to the customer can be selected and presented. Conversely, products that are likely of little interest to the customer can be deselected using the customer's profile information. By not presenting such products, the customer is aided in selecting which products to use or purchase.

Certain products may be highlighted or presented more prominently to the customer. For example, a product listing may be displayed in larger or bold font, it may include an image or a larger image, or it may be placed prominently on the display or list of results shown to the customer. Highlighted products may be included in a separate list from the rest of the products. These highlighted products can be products likely to be of particularly great interest to the customer, as determined by analyzing the customer's profile information. Alternately, certain brands or products may be highlighted for promotional or other reasons.

As the customer responds to the proposed product list, the product list may evolve. For example, if a customer requested to see all available ringtones but only selected ringtones from a particular genre of music, this information can be used to present or highlight other ringtones from that genre in the future.

In another aspect of the present invention, the user can interact with the website, a server, software, kiosk, etc. to select a product that configures, runs on, or is stored on a mobile terminal. In this case, it may be advantageous to send the product or products to the mobile terminal automatically upon selection and/or purchase. For example, if the customer purchases a ringtone, that ringtone can be sent directly to the customer's mobile terminal so it is available for near-immediate use. Advantageously, instructions can also be transmitted to the mobile terminal altering its configuration. For example, the mobile terminal can be instructed to use the new ringtone for some or all incoming calls.

If a mobile terminal is not already configured to receive instructions, software, or configuration changes from the network or other terminal, this functionality may be added to the terminal's software by an appropriate software application. This software application can be received, for example, over-the-air as a Wireless Application Protocol (WAP) push message.

As mentioned above, some products are, in whole or in part, an automatic configuration of a mobile terminal. For example, the customer can be offered the option of transferring his contact list from one terminal to another. Using such a system, the contact lists of multiple mobile terminals can be kept in sync. Of course, any type of profile information can be used, not just a contact list. For example, playlists, pictures, files, calendar information, font selections, terminal configurations, and application configurations can all be stored and transmitted to one or more terminals.

In yet another aspect of the invention, the customer may not know the profile information that can be used to recommend products. In this case, the customer may be presented with a test in order to determine the profile information. For example, if the user is seeking to buy a mobile terminal suitable for use by someone with a visual disability, it may be necessary to identify the extent of that disability. A test can be performed where the user is presented with text in various sizes. The user can then select the text size needed or desired. In this way, profile information on a minimum text size is obtained even if the user was unaware of his text size requirements or was unable to identify his requirements with numerical specificity.

Another example of a test is allowing the user to preview a product before purchasing it or permanently installing it. If a user is selecting software, a demo version of the software can be sent to the user to see if the software meets his needs. If the software is designed to run on a mobile terminal, this can be accomplished in at least three different ways.

One option is to send the user an application simulator, which is a software program that runs on the user's computer or mobile terminal. The instructions of the application simulator are not identical to the instructions of the mobile software it simulates, but its operation is identical to or similar to the operation of the mobile software. The application simulator may be a standalone program, or it may require another program to run. For example, the application simulator may run within the user's web browser as a Java applet or Adobe Flash presentation.

A second option is to send the user an emulator which mimics the operation of the hardware or application programming interface of a mobile terminal. The emulator is capable of executing the mobile software, thus eliminating the need to create an application simulator. By interacting with either an emulator or an application simulator, the user can test the usability and functionality of the product, such as mobile software, prior to installing it on his mobile device.

In addition to the above-described options, software similar to an application simulator can be used to simulate the user interface of hardware. A user selecting mobile terminals can be shown a simulated version of that mobile terminal. The user can thus interact with the buttons and test the features of the terminal without actually having it in hand. If a user selects to purchase a mobile terminal, his settings, configuration data, contact list, etc. can be retrieved and sent to the newly purchased mobile terminal. The simulated mobile terminal may contain an emulator capable of running software just like the actual mobile terminal would.

A third option for testing software designed to run on a mobile terminal is to send the user software that expires. The user receives a fully working application to run on the mobile device. After a pre-determined amount of time or after a pre-determined amount of use, the application will stop working.

A further example of a test can be to temporarily alter the configuration of the user's mobile terminal in order to determine if the user likes or dislikes the change. This can be accomplished by instructing the mobile terminal to implement the change. Then, after receiving feedback from the user or after a set period of time, instructing the mobile terminal to revert to its previous configuration. Of course, this reversion may not be necessary if the user selects to keep the new configuration and pays any required fees. The change can be as minor as modifying a font size or as major as a complete replacement of the terminal's software.

In another aspect of the present invention, information about available products can be received from an external server. This information can then be automatically presented to customers. Or it can be presented to customers if their profile information suggests likely interest in the underlying product. In cases where this information relates to third-party products or services, or in other cases, it may be advantageous to send information to an external server which causes the external server to deliver the product to the customer.

The following embodiments provide example combinations of some of the aspects described above. They are included for clarity, and are not intended to not limit the ways in which the above-described aspects may be implemented or combined.

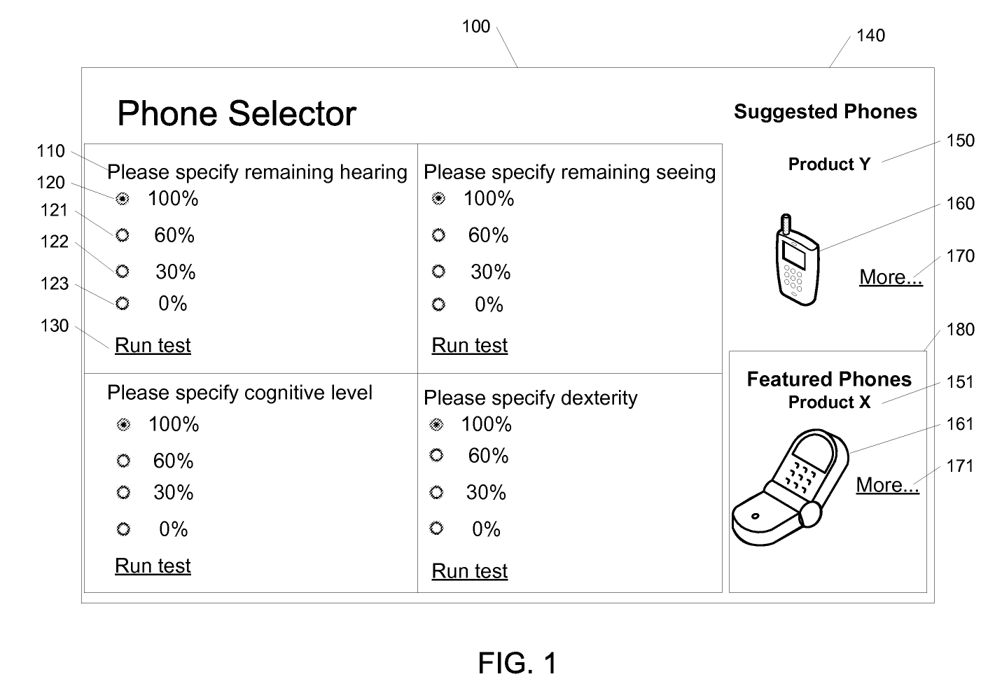

In one example embodiment of the present invention, illustrated in FIG. 1, a user interface, such as a website or an application's user interface, assists a disabled customer with selecting a user terminal, such as a mobile phone, that suits his needs. The display 100 and/or one or more speakers, such as the customer's headphones, asks a series of questions about the customer's level of ability or disability, such as question 110. The customer may answer using radio buttons 120-123 if the answer to the question is known. If it is not, the customer may click link 130, which launches a test designed to elicit or determine the answer to question 110. For example, tones of various pitches and volumes may be played in order to determine a customer's level of remaining hearing. The customer can indicate if and how clearly he heard the tones. These tones may be played over the customer's existing mobile handset or over his computer speakers, as appropriate. Playing the tones over the customer's handset can be accomplished by sending instructions to the handset's software to play the tones at a specified volume. If such software is not already on the handset, it can be sent to the handset as described above.

Alternately, the customer can be asked more general questions about his hearing, such as whether or not he is able to hear a refrigerator run. Upon completion of the test, the user interface will return to display 100, and the newly-determined profile information will be reflected by the filled-in selection of one of radio buttons 120-123.

Another alternative is to launch a simulator or emulator when link 130 is clicked. The simulator or emulator may present an actual mobile phone user interface or an application that simulates a user interface and interactively guides the user to test various features and configurations in order to select optimal applications, settings, and configurations. The simulator or emulator may also present the user with multiple different mobile terminals to choose from.

If the customer were to leave the user interface and return later, answers to the questions can be retrieved automatically, thus saving the customer from of entering profile information twice. The profile information collected by the website is used to provide a list of suggested products in right side column 140. Product names 150 and 151 are displayed, in addition to product photos 160 and 161. Links 170 and 171 lead to pages containing more detailed information about each phone.

Box 180 highlights one of the suggested products, which may be manufactured by the same company that sponsors the website.

If the customer selects one of the suggested phones, he may be given the option to purchase the phone. Alternately, the customer may print out a data sheet for use in identifying the phone when purchasing from another source.

If the customer is unsure of his phone selection choice, he may be shown a simulated version of the phone on his computer screen. In other words, the user interface simulates the phone. Using the simulated phone, the customer can experiment with the operation of the phone's buttons and familiarize himself with the interface. If the software on the phone can be configured, the customer may test various software configurations on the simulated phone and select the configuration which best suits his needs. This can be accomplished by simulating the operating system and applications of the phone, or by running an emulator. For example, user interfaces with increased text sizes and contrast may be shown to customers who indicate a partial visual disability. Advantageously, the phone may be shipped to the customer with the software configuration selected on the website. Alternately, details of the software configuration may be included on the data sheet so the customer can receive assistance in configuring the phone as desired.

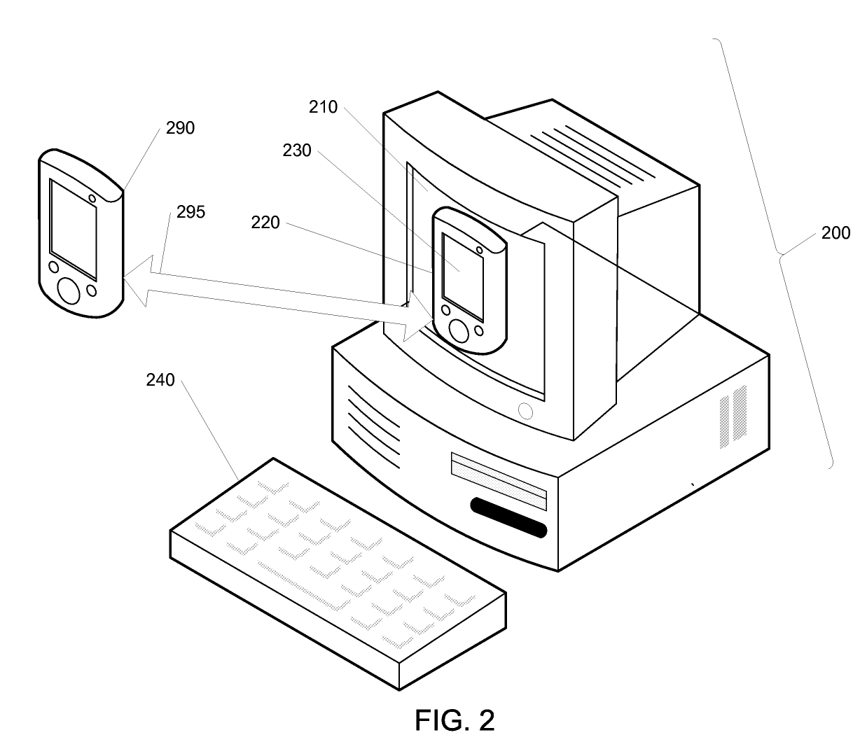

An example embodiment of the invention is illustrated in FIG. 2. A customer using computer 200 can test the operation of proposed customer software applications and/or terminals by viewing them on his computer screen 210. A simulated version of the customer's terminal, such as simulated mobile device 220, is displayed on screen 210. The emulated or simulated mobile software fills simulated display 230 with the same images that would normally appear on the display of the actual mobile device 290. Simulated device 220 can be a generic device rather than the user's actual mobile device. In some cases, it may be advantageous to display screen 230, but not the physical contours of simulated mobile device 220.

A customer testing software may end up configuring the customer software application. For example, if the customer is testing an e-mail client, he may enter his e-mail server name, username, and password into the version of the application displaying on screen 210. He can test the operation of the application with the entered settings, and he may alter the settings for optimal operation. If he ends up accepting the software application and installing it to his actual mobile device 290, the configuration of the software may also be transmitted to mobile device 290. This way the customer is saved from entering the same information twice. He has a readily working software application because the configurations made to the test application are reflected on his mobile device 290.

If the mobile software is simulated, then transferring the user's settings can be accomplished by copying the configuration files or settings created by the simulated application to the mobile device. If the mobile software is emulated, then these same files can be copied alone, or an image of an entire memory of the device can be transferred.

In an additional embodiment, the customer may use computer 200 to interact with mobile device software that he already owns in addition to products he is evaluating. The emulated device 220 and actual device 290 may be synchronized, as symbolically indicated by arrow 295. Changes made on emulated device 220 may propagate to actual device 290 and vice versa. This synchronization can be accomplished by copying an image of a memory of the mobile device to the emulator or by copying an image of a memory of the emulator to the mobile device. Alternately, only certain files, such as device or software configuration files, can be copied. The extent and direction(s) of data synchronization may optionally be configured by the user or system administrator. This synchronization may be advantageous because of the larger input means, such as full-sized keyboard 240, available on computer 200. Also, the backup copy of actual device 290's data may be transferred to a replacement device in the event of loss or theft, or in the event the user chooses to purchase a new mobile device.

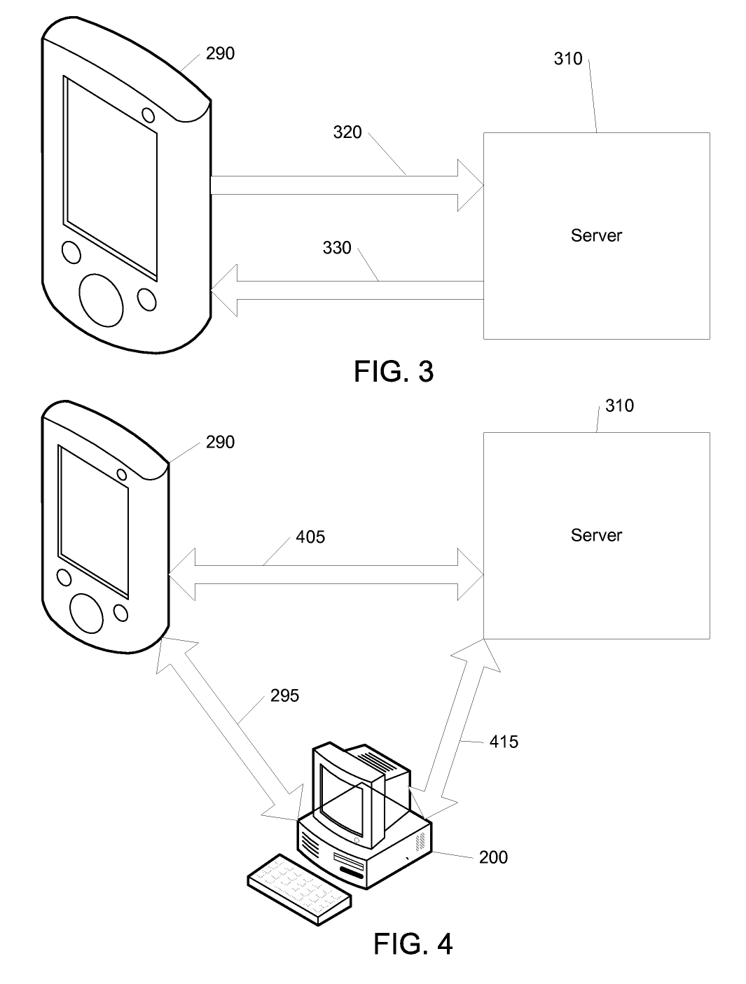

In one example embodiment of the invention, illustrated at FIG. 3, mobile device 290 sends data to server 310, as symbolically shown by arrow 320. This data is profile information, including calendar and contact information, media files and playlists, application usage data, and device configuration information such as user interface (UI) and application settings. Based upon analysis of the uploaded profile information, and possibly other profile information, server 310 may send proposed products to device 290, as symbolically indicated by arrow 330. If the user accepts the proposed products, then the products may be sent directly to the mobile device. Alternately, instructions for how to obtain the product may be sent to the mobile device.

In another embodiment, mobile device 290 creates a synchronization process and/or request to server 310. In this synchronization process, the mobile device 290 sends current profile information to server 310. Server 310 compares this current profile information to profile information on the server. If there is new profile information, such as new user interface settings, new media playlists, or new media content, then server 310 sends the new profile information to mobile device 290. The new information sent to the mobile device may include proposed products. If so, the user may test the proposed software, settings, content, etc. If any of the proposed products are limited or trial versions, then the user may request to download a full version. If the proposed products are device configurations, then the user may request to make the proposed changes permanent. In one example embodiment, the user has an account in the OVI service by Nokia Corporation, which is available at www.ovi.com. Data may be synchronized between a mobile terminal and a server using this service. At least part of the data collected from the terminal may be profile information that is used by the server to suggest potential new products, such as a new mobile device for the user. The collected profile information may also be used to suggest or pre-select answers to questions, such as question 110 shown in FIG. 1. The user may amend the suggested answers by answering the questions manually or by running a test designed to determine an answer to the question. For example, the user may follow link 130 in FIG. 1.

In yet another example embodiment of the invention, illustrated at FIG. 4, server 310 sends product suggestions when specifically requested by a terminal, such as mobile device 290 or computer 200. The suggestions are made based on profile information transmitted along communications link 405 and optionally based on profile information transmitted along communications link 415. Advantageously, server 310 may also utilize further profile information when determining which products to suggest. If a product is selected, it may be sent along link 405, or it may be sent along link 415 to the user's computer. In this case, the software may be installed on mobile device 290 via communications link 295. Examples of communications link 295 include Universal Serial Bus (USB) cables and short range wireless connection, such as Bluetooth wireless connections.

In another embodiment, the terminal, such as mobile device 290, creates a synchronization process and/or request to server 310. In this synchronization process the mobile device 290 sends current profile information to server 310. The synchronization process may occur periodically or upon occurrence of an event. The sending and/or receiving of information during the synchronization process may occur automatically and without any user notification or interaction.

Server 310 analyzes the profile information and prepares new profile information that may be sent back to mobile device 290. The new profile information may include proposed products and is based upon the present profile information as well as the available services, content, devices, etc. The new profile information and proposed products may be sent automatically, when the next automatic synchronization is requested, or when the user initiates a request.

If there are any updates to the profile information, including proposed products such as new user interface settings, new media playlists, new media content, etc., then server 310 may send the new profile information and/or products to computer 200. When this occurs, the user can test the proposed products on computer 200. This may be desired because of the larger display and full QWERTY keyboard available on computer 200. The user may request that some or all of the proposed products be sent to his mobile device via server 310, or via computer 200.

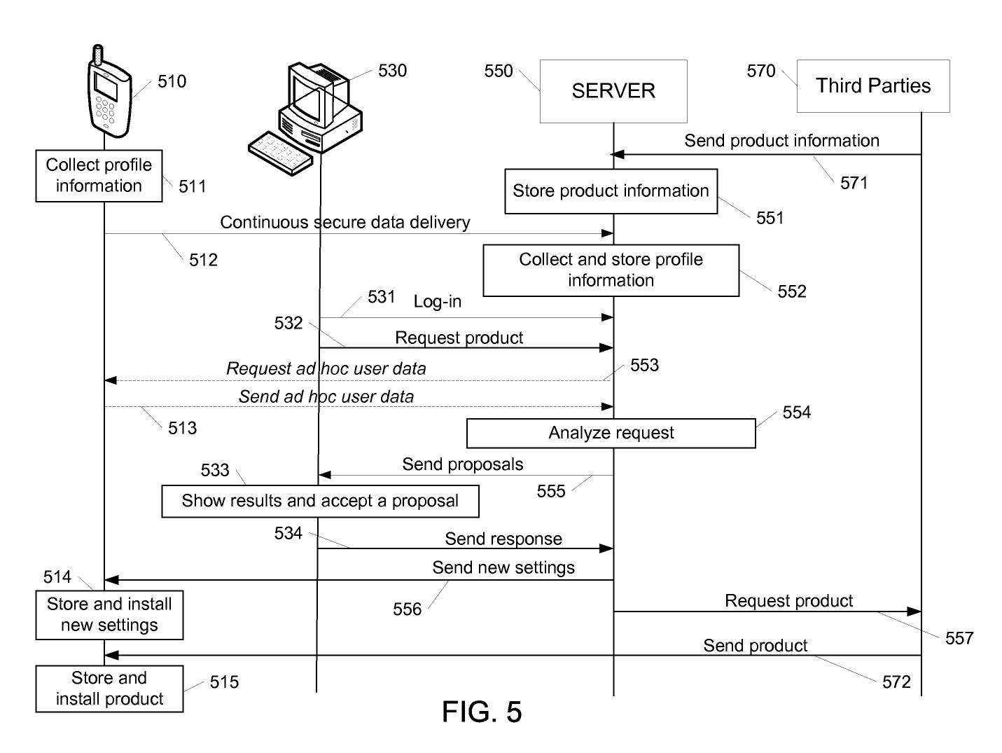

FIG. 5 illustrates various example embodiments of the present invention by diagrammatically illustrating the flow of information between mobile terminal 510, computer 530, server 550, and third parties 570. The third parties may be one or more terminals. These terminals may be operated by the same entity that operates server 550, or they maybe operated by different entities.

Mobile terminal 510 may be a wireless or a wired terminal, such as a mobile device, mobile phone, mobile computer, mobile communication device, personal digital assistant (PDA), audio/video player, digital camera/camcorder, positioning device, mobile television, radio receiver, game device, and/or the like, or any combination thereof.

Computer 530 may be a wireless or a wired computer, such as a personal computer, personal server, mobile computer, mobile communication device, personal digital assistant (PDA), audio/video player, digital camera/camcorder, positioning device, television, radio receiver, game device, and/or the like, or any combination thereof.

Server 550 may be one or more network servers and/or a service provider, such as Yahoo™ and Google™. The third parties 570 may be product provider providing media, software applications, hardware terminals and/or the like.

In some embodiments, at least some of the product information originates from third parties 570 and is transmitted to server 550 in transmission 571. Server 550 stores this information in step 551. Alternatively, server 550 and the third parties may be combined into a single physical or logical device.

Mobile device 510 collects profile information at step 511 and it sends some or all of the information to server 550 on a continuous basis, as indicated by transmission 512. For example, information can be sent to server 550 as soon as it becomes available. It is to be understood that transmission 512 does not have to occur on a continuous basis. It can also occur periodically, or upon the occurrence of certain events. Alternately, it can be replaced entirely by optional transmission 513, as will be discussed more fully below.

It is also to be understood that mobile device 510 may synthesize some or all of the collected profile information and send the synthesis in transmission 512 and/or transmission 513. For example, mobile device 510 may send the most common categories of music selected by the user instead of sending the list of songs actually played, or it may indicate that the user sends more than a predetermined number of text messages a day instead of reporting the actual usage.

Server 550 stores the profile information from transmission 512, along with any other profile information it may have.

Upon transmissions 531 and 532, the server receives a request for a product from terminal 530. Similar communications could have come from mobile terminal 510. In response to the request, server 550 optionally requests ad hoc user data in transmission 553 and receives it in transmission 513. This ad hoc user data is profile data not included in transmission 512, or it may be an update of the profile data last sent in transmission 512. The precise data transmitted in elements 553 and 513 may depend on the type of product being requested. For instance, the genres of must that a user listens to may be uploaded in transmission 512, but the list of individual songs played by the user may be uploaded in transmission 513 if the user is requesting to see the catalog of available music. The list of individual songs may be used to predict other songs the user is likely to purchase based on correlations with the listening habits of other users. The list can also be used to avoid suggesting a song to the user that he already owns.

Using the received profile data, server 550 determines one or more products to propose at step 554, and it sends those proposals in transmission 555. The proposals may include a test, such as emulation and/or simulation software. Terminal 530 displays the proposals and any included emulations or simulations at step 533. The user accepts one or more of them. The user's acceptance is sent in transmission 534. If the accepted product is one that requires new settings to be sent to mobile device 510, those settings are sent in transmission 556.

Although server 550 may be able to transmit some products directly to mobile device 510, in this case the product will be sent from third parties 570. The server requests that the accepted product be sent to mobile device 510 in transmission 557. The product is then sent in transmission 572. If the product needs to be installed, installation occurs at step 515 in accordance instructions that are sent with the product or that were sent in transmission 556.

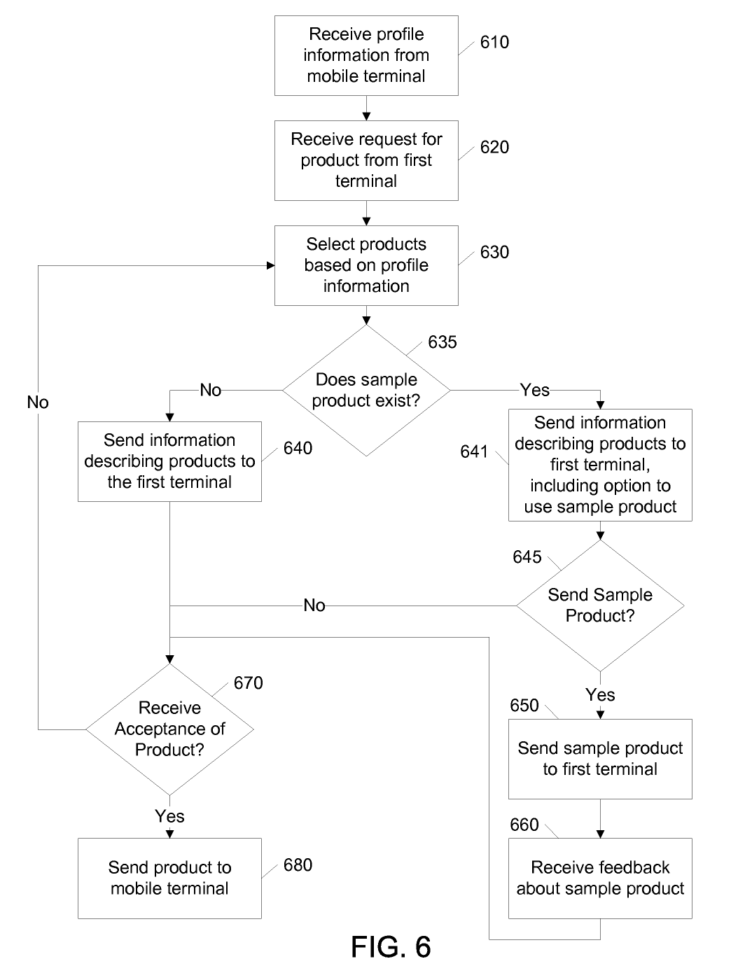

FIG. 6, an example embodiment of the invention, shows a flowchart including method steps for assisting customers with product selection. In step 610, profile information is received from a mobile terminal, such as the mobile terminal 510. As discussed above, profile information can be sent automatically by the mobile terminal. It can be sent periodically or upon the occurrence of certain events, such as new information becoming available. Alternatively, profile information can be received from a mobile terminal in response to a request made to the mobile terminal.

In step 620, a request for a product or products is received from a first terminal. The first terminal can be the same terminal as the mobile terminal, or it can be a different terminal. For example, a request from the first terminal, such as computer 530, can be a request from a user at his home computer for a new ringtone. Step 620 may occur before step 610. Profile information may be received after the request for products is received.

In step 630, products are selected based on the information received in steps 610 and 620. To continue to ringtone example, ringtones can be selected that have a similar bass beat to the songs played most often by a user, as indicated by the user's profile information.

If one or more samples of the products are available, as shown in step 635, then information about the products, which includes information about optionally using the samples of the products, can be sent to the first terminal in step 641. For example, if a sample of a ringtone is available, then the artist and the song title of the ringtone may be sent to the user. A link to an audio recording of the ringtone may also be sent.

If a sample of the product does not exist or is not to be sent to the user for some other reason, then information about the product can be sent to the first terminal in step 640.

If a sample is available, it may be sent to the first terminal automatically in step 650. Alternately, the sample product may be sent upon receipt of a request for the sample product. Decision 645 represents that both of these possibilities exist.

If a sample is sent, feedback may be received about the sample product in optional step 660. For example, a rating of how much a user likes or dislikes a song can be received.

If acceptance of a product is received, then the product may be sent to a mobile terminal in optional step 680. After step 680, step 630 may be repeated. If acceptance is not received, then step 630 can also be repeated. That is, more products may be selected and information about those products may then be sent.

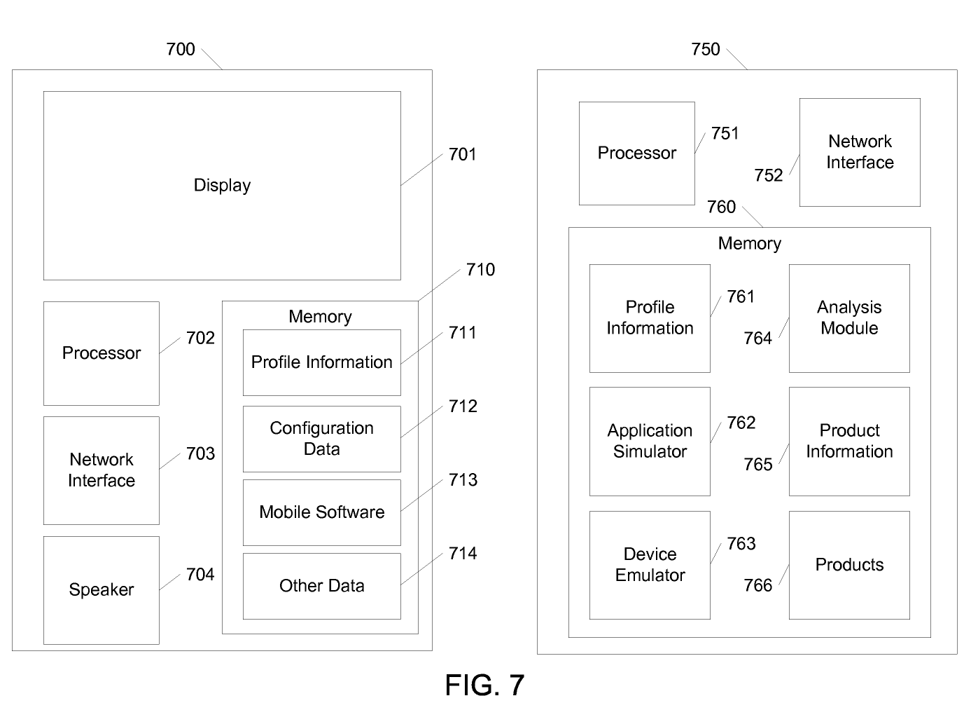

FIG. 7, an example embodiment of the invention, shows an example of terminals in which the principles of the invention can be practiced. Terminal 700, such as the user terminal 510, includes display 701, processor 702, network interface 703, speaker 704, and memory 710. One or more displays, processors, network interfaces, speakers, or memories may exist in mobile device 700. Network interface 703 allows the mobile device to receive and transmit data. Network interface 703 can be a wireless network interface, such as a chipset for sending and receiving data over a cellular network. Memory 710 contains instructions that can be executed by processor 702. These instructions are collectively identified as mobile software 713. Memory 710 may also contain profile information 711. Configuration data 712, which represents how the device is configured, may also be within memory 710. Examples of configuration data include the volume level and display scheme of the mobile device. Finally, memory 710 may include other data, such as music files.

Computer 750, such as computer 530 and/or server 550, includes processor 751, network interface 752, and memory 760. One or more processors, network interfaces, or memories may exist in computer 750. Memory 760 contains instructions that can be executed by processor 751. These instructions have not been collectively identified in FIG. 7, but they include analysis module 764. Analysis module 764 is software that uses profile information 761 and product information 765 to select proposed products. Information about the selected proposed products may be sent via network interface 752. Memory 760 may also contain application simulators, such as application simulator 762, or device emulators, such as device emulator 763. It may also contain products 766. Products 766 are products capable of being stored in memory, such as movies or software.

Embodiments of the present invention may be implemented in software, hardware, application logic or a combination of software, hardware and application logic. The software, application logic and/or hardware may reside on the memory 710 in the terminal 700, or the memory 760 in the computer 750. The application logic, software or an instruction set is preferably maintained on any one of various conventional computer-readable media. In the context of this document, a “computer-readable medium” may be any media or means that can contain, store, communicate, propagate or transport the instructions for use by or in connection with an instruction execution system, apparatus, or device.

If desired, the different functions discussed herein may be performed in any order and/or concurrently with each other. Furthermore, if desired, one or more of the above-described functions may be optional or may be combined.

Although various aspects of the invention are set out in the independent claims, other aspects of the invention comprise any combination of features from the described embodiments and/or the dependent claims with the features of the independent claims, and not solely the combinations explicitly set out in the claims.

It is also noted herein that while the above describes example embodiments of the invention, these descriptions should not be viewed in a limiting sense. Rather, there are several variations, combination and modifications of the embodiments which may be made without departing from the scope of the present invention as defined in the appended claims.

I claim:

1. An apparatus comprising:
a processor, the apparatus configured to:
receive a request for a product from a first terminal;
receive profile information of a user from a mobile terminal; and
send information describing at least one proposed product to the first terminal, wherein the proposed product is selected based upon an analysis of the request and the profile information of the user.

2. The apparatus of claim 1, further comprising a memory configured to store therein processor executable instructions.

3. The apparatus of claim 1, further configured to send at least one accepted product to the mobile terminal.

4. The apparatus of claim 1, further configured to determine profile information of the user by presenting a test to said user at the first terminal.

5. The apparatus of claim 4, wherein the test is an application simulator that simulates a proposed software configuration or the execution of a proposed software product on a mobile device.

6. The apparatus of claim 4, wherein the test emulates the operation of a second mobile terminal.

7. The apparatus of claim 1, further configured to send configuration data to the mobile terminal, wherein the configuration data is received as a result of user input at the first terminal to at least one of an application simulator or software running on an emulator.

8. The apparatus of claim 1, wherein the received profile information is synchronized between the mobile terminal and the apparatus.

9. One or more computer-readable media having stored thereon executable instructions that, when executed by a computer, perform:
receiving a request for a product from a first terminal;
receiving profile information of a user from a mobile terminal; and
sending information describing at least one proposed product to the first terminal, wherein the proposed product is selected based upon an analysis of the request and the profile information.

10. The one or more computer-readable media of claim 9, wherein the instructions, when executed, also perform:
sending at least one accepted product to the mobile terminal.

11. The one or more computer-readable media of claim 9, wherein the instructions, when executed, also perform:
presenting a test, which determines profile information, to the user.

12. The one or more computer-readable media of claim 9, wherein the instructions, when executed, also perform:
sending to the first terminal an application simulator that simulates a proposed software configuration or the execution of a proposed software product on a mobile device.

13. The one or more computer-readable media of claim 9, wherein the instructions, when executed, also perform:
sending to the first terminal software that emulates the operation of a proposed mobile terminal.

14. The one or more computer-readable media of claim 9, wherein the instructions, when executed, also perform:
sending pre-configured software to the mobile terminal, wherein the pre-configuration is based on data received from the first terminal.

15. The one or more computer-readable media of claim 9, wherein the accepted product is a second mobile terminal, and wherein the instructions, when executed, also perform:
sending profile information of the user to the second mobile terminal.

16. A method comprising:
receiving a request for a product from a first terminal;
receiving profile information of a user from a mobile terminal;
analyzing the request and the profile information in order to select one or more proposed products; and
sending information describing one or more proposed products to the first terminal.

17. The method of claim 16, further comprising:
sending at one or more accepted products to the mobile terminal.

18. The method claim 16, further comprising:
determining profile information of the user by presenting a sample product to the user.

19. The method of claim 18, wherein the sample product is an application simulator that simulates a proposed software configuration or the execution of a proposed software product on a mobile device.

20. The method of claim 18, wherein the sample product is software that emulates a second mobile terminal.
